(19) United States
(12) Patent Application Publication
(10) Pub. No.: US 2025/0300030 A1
(43) Pub. Date: Sep. 25, 2025

(54) ELECTRONIC POWER SUBSTRATE FOR ENHANCED SINTERING

(71) Applicant: SEMICONDUCTOR COMPONENTS INDUSTRIES, LLC, Scottsdale, AZ (US)

(72) Inventors: Shutesh KRISHNAN, Seremban (MY); Jerome TEYSSEYRE, Singapore (SG)

(73) Assignee: SEMICONDUCTOR COMPONENTS INDUSTRIES, LLC, Scottsdale, AZ (US)

(21) Appl. No.: 18/612,026

(22) Filed: Mar. 21, 2024

(51) Int. Cl. H01L 23/15; H01L 21/02; H01L 21/324; H01L 21/67

(52) U.S. Cl. CPC H01L 23/15; H01L 21/02178; H01L 21/02458; H01L 21/324; H01L 21/67144

(57) ABSTRACT

An apparatus includes a ceramic substrate. A first metal layer is disposed on a first side of the ceramic substrate, and a second metal layer is disposed on a second side of the ceramic substrate. The second meta layer has an outer surface including a mechanical interlocking feature.

### TECHNICAL FIELD

This description relates to packaging of semiconductor die and integrated circuits.

### BACKGROUND

A semiconductor device package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The package provides a means for connecting the semiconductor devices or integrated circuits to the external environment, such as printed circuit board, via leads such as lands, balls, or pins; and protection against threats such as mechanical impact, chemical contamination, and light exposure. For some applications (e.g., inverter or other circuit applications) to dissipate heat that may be generated in the semiconductor device package, the package can be surface mounted on a heat sink block or a metal casing of an application component or module (e.g., inverter module) itself. With increasing demand for high-performance ICs, new improvements are needed in packaging technologies to bring out the ICs' performance and reliability.

### SUMMARY

In a general aspect, an apparatus includes a ceramic substrate. A first metal layer is disposed on a first side of the ceramic substrate, and a second metal layer is disposed on a second side of the ceramic substrate. The second meta layer has an outer surface including a mechanical interlocking feature.

In a general aspect, a substrate includes a ceramic substrate; and a metal layer disposed on a side of the ceramic substrate. The metal layer includes a plurality of mechanical interlocking features for engaging and holding on to a joining material layer.

In a general aspect, a method includes forming a mechanical interlocking feature on a surface of a metal layer. The method further includes disposing a layer of joining material on a surface of an electronics application component, disposing the metal layer with the mechanical interlocking feature on the layer of joining material, and forming a joint between the metal layer and the surface of the electronics application component.

The details of one or more implementations are set forth in the accompanying drawings and the description below. Other features will be apparent from the description and drawings, and from the claims.

### BRIEF DESCRIPTION OF THE DRAWINGS

FIG. 1 illustrates an example semiconductor device package that is surface mounted on a metal surface of an inverter with a mechanical interlocking feature disposed between the semiconductor device package and the inverter.

FIG. 2A illustrates an example power electronic substrate in which a surface texture of the surface of a bottom metal layer of the power electronic substrate includes mechanical interlocking features such as cuts, grooves, indentations, and/or so forth formed in the surface of a bottom metal layer.

FIG. 2B illustrates an exploded view of a portion A of the bottom metal layer of FIG. 2A.

FIG. 3A illustrates an example power electronic substrate in which a surface texture of the surface of a bottom metal layer of the power electronic substrate includes mechanical interlocking features such as bumps, protrusions, and/or so forth formed on the surface of a bottom metal layer.

FIG. 3B illustrates an exploded view of a portion B of the bottom metal layer of FIG. 3A.

FIG. 4 illustrates a cross sectional view of a semiconductor device package that is surface mounted on a heat sink block.

FIGS. 5A through 5C pictorially illustrate different distributions of the interlocking features on the backside of a metal layer at the bottom of power electronic substrate.

FIG. 6 illustrates an example method for sintering a surface-mounted semiconductor device package to a metal surface of an electronics application component.

### DETAILED DESCRIPTION

A semiconductor device package (e.g., an integrated circuit (IC) package) includes a semiconductor die mounted on a lead frame structure that includes leads providing external electrical connections (external to the package) for individual devices or integrated circuits in the semiconductor die. The semiconductor die can be mounted on a paddle or flag in the leadframe structure using a solder or a conductive adhesive. Further, device contact pads on the semiconductor die are electrically connected using wire bonds (e.g., aluminum wire bonds) to respective ones of the leads. The leads, which extend to an outside of the package body, form external terminal pins that can be used to mount the package on a printed circuit board or terminal strip. In example implementations, the terminal pins can be installed in sockets or soldered to a printed circuit board (PCB) or terminal strip.

In example implementations, the semiconductor device package can be a hybrid device package that includes a plurality of semiconductor dies that are integrated onto to a unifying substrate. The different semiconductor dies may be fabricated on different semiconductor wafers or materials. For example, the plurality of semiconductor dies in the package may include a first die formed using a silicon (Si) material and a second die formed using a silicon carbide (SiC) material.

For power applications (e.g., automotive applications), the semiconductor package (hereinafter power module) may include silicon carbide transistors, gallium nitride devices, or insulated gate bipolar transistor (IGBT), fast recovery diode (FRD), or other devices.

In example implementations, a power semiconductor device may be mounted on an electronic power substrate in the power module. The electronic power substate includes a ceramic substrate. The ceramic substrate may be metalized (e.g., as a direct bonded copper (DBC) substrate, or an advanced metal brazing (AMB) substrate) with metal layers that are plated, bonded, or formed on each side of a ceramic substrate in the power module. The DBC can be referred to as a direct bonded metal (DBM) if a different material other than copper (or an alloy thereof) is used.

In some implementations, DBC substrates are used in some power modules, because of their very good thermal conductivity. In some implementations, a DBC substrate is composed of a ceramic oxide substrate (baseplate) with a layer of copper coupled to one or both sides by, for example, a high-temperature oxidation process (e.g., the copper and baseplate are heated to a carefully controlled temperature in an atmosphere of nitrogen containing about 30 ppm of oxygen; under these conditions, a copper-oxygen eutectic forms which bonds successfully both to copper and the ceramic oxide baseplate). In some implementations, the top copper layer can be pre-formed prior to firing or chemically etched using printed circuit board technology to form traces of an electrical circuit, while the bottom copper layer can be maintained as a solid layer. In some implementations, the bottom copper layer can function as, for example, a heat sink.

In some implementations, an AMB substrate has electrical properties similar to that of DBC substrate. In some implementations, an AMB substrate consists of a metal foil soldered to the ceramic substrate using solder paste and high temperatures (800° C.-1000° C.) under vacuum.

In accordance with the principles of the present disclosure, the bottom copper layer of the DBC substrate (or the AMB substrate) can have a textured surface. The textured surface can include mechanical interlocking features (also can be referred to as a mechanical interlocking mechanism or as mechanical interlocking mechanisms) such as cuts, grooves or indentations in the surface, or bumps or protrusions extending from the surface of the bottom copper layer.

In example implementations, the bottom copper layer of the DBC substrate (or of the AMB substrate) can be attached to a heat spreader or a heat sink using metallurgical joining techniques such as soldering or sintering. In some example implementations. silver sintering techniques may be used to attach the bottom copper layer of the DBC substrate (or of the AMB substrate) to a surface of the heat spreader or the heat sink.

In some implementations, the power semiconductor device, and other components (e.g., a lead frame substrate) of the power module may be encapsulated in a molding material body (e.g., body made of a plastic or an epoxy, etc.). In some implementations, pins, or terminals (e.g., signal pins, power terminals) may extend to outside the power module. In an example implementation, a semiconductor device package excluding pins can, for example, be a rectangular box-like structure with a width W, a height H, and a length L.

In example implementations, the power module can be a surface-mount package with exposed a copper thermal pad at a bottom of the module. The exposed copper thermal pad may, for example, be formed by a metal layer of the ceramic substrate of the DBC or AMB substrate on which the semiconductor power semiconductor device is mounted. In example implementations, enhanced thermal performance may be realized when the power module is surface mounted on and bonded on a heat sink block or a metal casing of the application component or module (e.g., inverter module) itself. In this configuration, heat generated in the power module may pass through the copper thermal pad at a bottom of the power module to the heat sink block or the metal casing of the application component or module.

In example semiconductor device packages (power modules), the relative temperature of various package components during package fabrication as well as during device operation can affect the mechanical stability and the electrical reliability of the package components.

In some example implementations, the bottom surface of the power module (in other words, the copper thermal pad at the bottom surface of the power module) may be soldered to a surface of a heat sink block or the metal casing of the application component or module (e.g., inverter module).

In some example implementations, the bottom surface of the power module (in other words, the copper thermal pad at the bottom surface of the power module) may be sinter bonded to a surface of the heat sink block or the metal casing of the application component or module (e.g., inverter module). A sinter material layer may be disposed between the bottom surface of the power module and the surface of the heat sink block or the metal casing. The sinter material layer may, for example, be a paste including micron or sub-micron sized metal particles or flakes. The metal particles or flakes may, for example, include metals such as silver, copper, iron, nickel, molybdenum, or copper.

In some example implementations, the bottom surface of the power module may be attached to the surface of the heat sink block or the metal casing by an Ag sinter bond. Forming the Ag sinter bond may involve silver (Ag) sintering at a sinter temperature (Ts) and a sinter pressure (Ps). The Ag sinter material used may, for example, be a silver particle paste disposed between the two surfaces. The adhesion between the two surfaces that are silver sintered can be a function of the sinter temperature Ts and sinter pressure Ps. Silver has a melting point of about 900° C. However, such a high sintering temperature (or a high sintering Ps) can damage, for example, the semiconductor device in the power module. Therefore, in example implementations, low temperature silver sintering may be used in a trade-off with the strength of the adhesion between the two surfaces. The Ag sintering may involve a low temperature sintering treatment in addition to application of pressure to the components. In example implementations, the low temperature sintering may involve sintering temperatures, for example, in a range of about 200° C. to about 400° C. (e.g., 250° C.).

In example implementations, a layer of silver sinter material (e.g., a silver particle paste) may be disposed on the surface of heat sink block (or the metal casing of the application) to which the power module is to be attached. The power module may be placed on the surface of heat sink block with the textured bottom surface of the power module in contact with the layer of silver sinter material. The assembly may be placed in a jig to apply pressure to the combination of the power module and the heat sink block, and heated (e.g., in an oven) at low temperatures (less than 400° C., e.g., 250° C.). In a heat and pressure based sintering process, a sinter species (e.g., Ag atoms) may diffuse from the layer of silver sinter material into the bottom surface of the power module and the surface of the heat sink block, and hold the two different components together. Sintering improves reliability of the attachment (bonding) of the two components together by avoiding use of an intermediate joining layer (e.g., a solder or adhesive) that can crack, for example, on temperature cycling.

In accordance with the principles of the present disclosure, a mechanical interlocking feature is disposed between a bottom surface of the power module and the surface of the heat sink block or the metal casing of the application component or module. The mechanical interlocking feature interlocks with a joining material layer (e.g., a solder material layer or a sinter material layer) that may be disposed the bottom surface of the power module and the surface of the heat sink block or the metal casing. In example implementations, the mechanical interlocking feature interlocks with the joining material layer. The mechanical interlocking feature may, for example, interlock with a sinter material layer such silver particle paste, and enhance the strength of a silver sinter bond or joint between the two surfaces (in other words, increase the adhesion strength of the power module and the surface of the heat sink block or the metal casing of the application component or module).

In example implementations, the mechanical interlocking feature may include interlocking features formed on the bottom surface of the power module. The interlocking features may, for example, include at least one of V-shaped grooves, U-shaped grooves, or protrusions or bumps formed on the bottom surface of the power module. The interlocking features formed on the bottom surface of the power module mechanically interlock with the sinter material disposed between the power module and the surface of the heat sink block or the metal casing of the application component or module. The interlocking features may engage and hold the sinter material layer (or solder material layer) in place and prevent sliding of the power module on the surface of heat sink block or the metal casing.

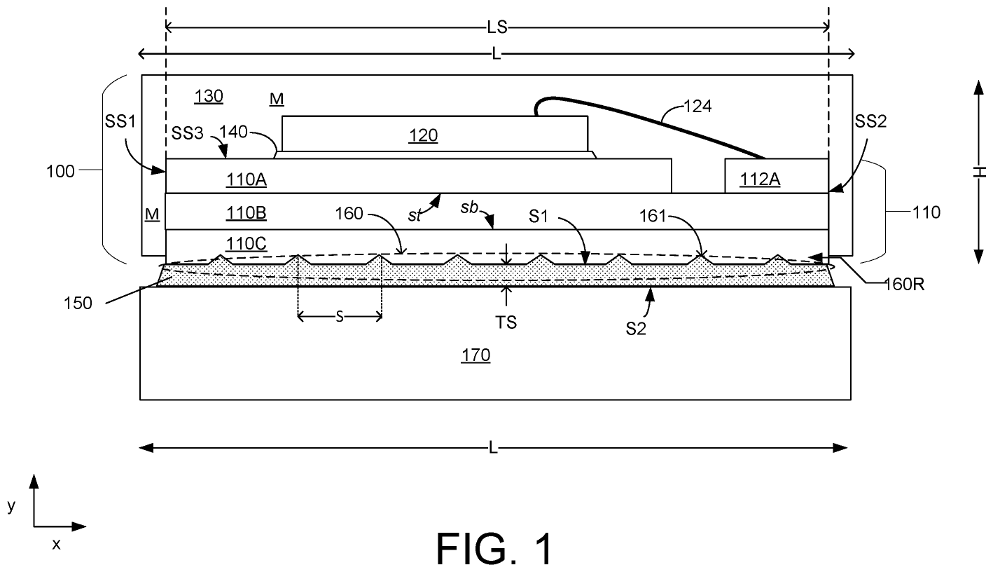

FIG. 1 shows a cross sectional view of a semiconductor device package 100 that is surface mounted on a heat sink block 170. Semiconductor device package 100 is adhered to heat sink block 170 by a joining material layer (e.g., silver sinter material layer 150) and a mechanical interlocking feature 160. In example implementations, the layer of sinter material may be a silver particle paste.

Semiconductor device package 100 includes, for example, a mold body 130 made of a plastic or an epoxy, etc. Mold body 130 may be made of a plastic and/or an epoxy material M. Mold body 130 may for example have a length L (in the x-direction) and a height H (in the y-direction).

Mold body 130 may enclose a semiconductor device die 120 disposed on a power electronic substrate 110. Power electronic substrate 110 may have a length LS, for example, in the x-direction, between sides SS1 and SS2. The plastic or epoxy material of mold body 130 may be disposed on a top surface SS3 of power electronic substrate 110 to enclose semiconductor device die 120. In example implementations, the length LS of the power electronic substrate may be the same as, or less than, the length L of mold body 130. In instances where the length LS of the power electronic substrate is less than the length L of mold body 130, as shown in FIG. 1, the plastic or epoxy material M of mold body 130 may extend over (cover) sides SS1 and SS2 of power electronic substrate 110.

Power electronic substrate 110 may, for example, include a high thermal conductivity ceramic substrate 110B. A metal layer 110A may be bonded to a top surface st of ceramic substrate 110B and another metal layer 110C may be bonded to a bottom surface sb of ceramic substrate 110B. Ceramic substrate 110B may disposed (e.g., sandwiched) between metal layers 110A and 110C. In some example implementations, power electronic substrate 110 may, for example, be a direct bonded copper (DBC) substrate in which ceramic substrate 110B is made of alumina (Al₂O₃) or aluminum nitride (AlN), and metal layers 110A, 110C are formed of plated or bonded copper. In some other implementations, power electronic substrate 110 may, for example, be an active metal brazing (AMB) substrate in which ceramic substrate 110B is made silicon nitride (Si₃N₄), and metal layers 110A, 110C are formed by brazed copper sheets.

Semiconductor device die 120 may be disposed on metal layer 110A and bonded to the power electronic substrate 110, for example, by a silver sinter layer 140. Further, interconnections between device contact pads (e.g., source contact pads, not shown) on semiconductor device die and terminals (e.g., terminal 112A) on the power electronic substrate 110 may be made by wire bonds (e.g., wire 124). In some implementations, the interconnections may be made a metal clip (not shown).

A bottom surface S1 of metal layer 110C forms an exposed a copper thermal pad at a bottom of the semiconductor device package 100.

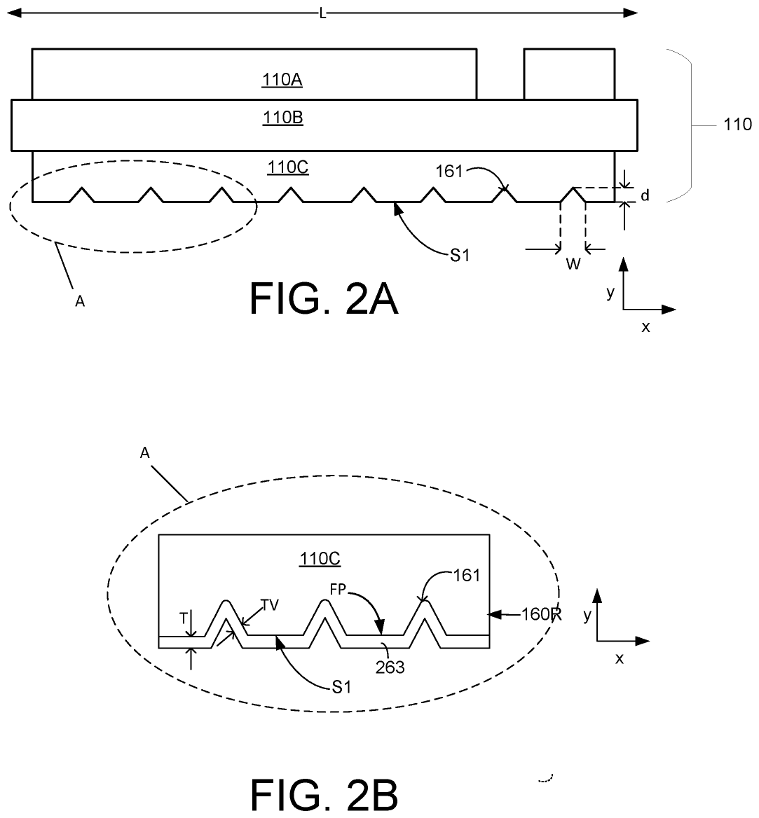

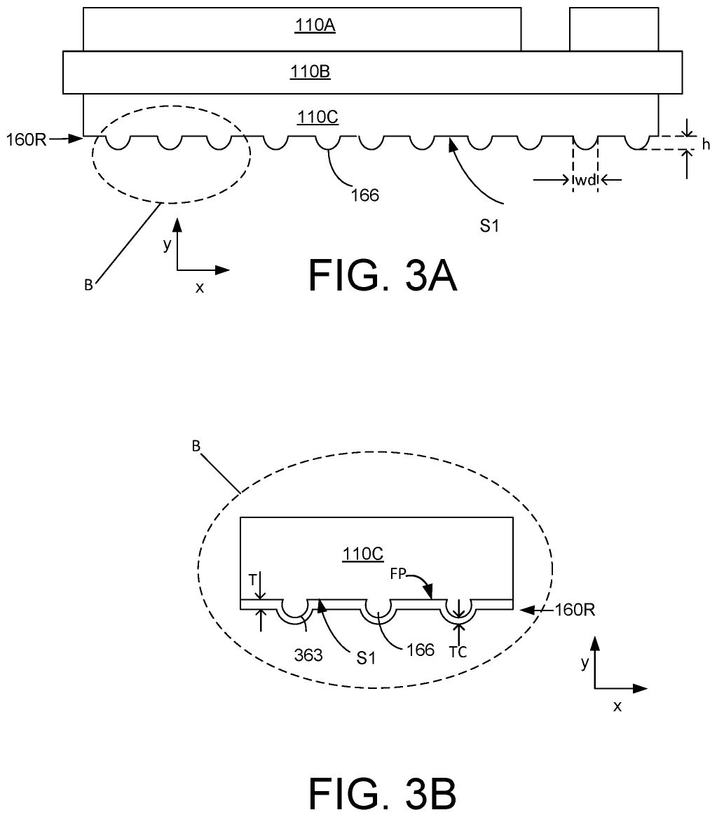

In example implementations, the bottom surface S1 of metal layer 110C may be textured (e.g., roughened) to form a mechanical interlocking feature 160. The bottom surface S1 of metal layer 110C may be referred to as the roughened surface or the textured surface herein. In example implementations, the textured surface may be formed by texture features such as cuts, grooves, notches and/or so forth, into, or protrusions extending from, the bottom surface S1 of metal layer 110C. In example implementations, the texture features (cuts, grooves, or notches, or protrusions) may be regularly spaced or may be irregularly or unevenly spaced across the bottom surface S1 of metal layer 110C. In example implementations, each texture feature (cut, groove, or notch, or protrusion) (as shown for example, in FIG. 2A) may have a width (w) in the x-direction and a vertical depth or height (h) in the y-direction. In example implementations, the width w may, for example, be in a range of about 100 μm to 150 μm, and the height h may also, for example, be in a range of about 100 μm to 150 μm.

In some example implementations, the texture features may have a constant or uniform areal density, for example, in the x and y directions, across the bottom surface S1 of metal layer 110C. In some other example implementations, the texture features may have a non-constant or varying areal density across the bottom surface S1 of metal layer 110C. For example, some areas (e.g., an edge portion or area) of the bottom surface S1 may have a higher or a lower areal density of texture features than other areas (e.g., a central portion or area) of the bottom surface S1.

FIG. 1 shows, for example, a pattern of V-shaped notches 161 in the bottom textured surface S1 of metal layer 110C. The pattern of V-shaped cuts or notches 161 may, for example, be a row 160R of the V-shaped cuts or notches along a length LS (in a x-direction) of bottom textured surface S1 of metal layer 110C. In example implementations, the texture features V-shaped cuts or notches 161 may be generally evenly spaced with an inter-feature spacing S. In example implementation, the inter-serration spacing S may be in a range of about 100 μm to 1000 μm.

In example implementations, the textured bottom surface S1 of semiconductor device package 100 is bonded to a top surface S2 of a component (inverter casing, or heat sink block 170) by a silver sinter material layer 150. Silver sinter material layer 150 may, for example, be a paste containing silver particles. In example implementations, silver sinter material layer 150 may have thickness T (e.g., in the y direction). In example implementations, thickness T may be a thickness in a range of about 200 μm to 5000 μm. The silver sinter bonding of the textured bottom surface S1 of semiconductor device package 100 to the top surface S2 of the component (inverter casing, or heat sink block 170) may be accomplished by a low temperature sintering process. The low temperature sintering process may involve sintering temperatures, for example, in a range of about 200° C. to about 400° C. (e.g., 250° C.). The silver sinter adhesion or bonding joint formed at low temperatures between the two surfaces S1 and S2 is reinforced and strengthened by mechanical interlocking feature 160. Mechanical interlocking feature 160 may prevent displacement of the two surfaces S1 and S2 relative to each other or relative to the silver sinter material layer 150.

In example implementations, the mechanical interlocking features are formed in or on a bottom metal layer of a ceramic substrate included in the semiconductor device package. The mechanical interlocking features may take the form of protrusions or indentations. In example implementations, the interlocking features at the bottom of the ceramic substrate may be fabricated using methods such as chemical etching, mechanical stamping, or laser cutting, etc. of the in or on the bottom metal layer of the ceramic substrate.

In example implementations, the mechanical locking features and the textured surface are covered with a thin layer of silver to facilitate sintering. In example implementations, the mechanical locking features may be covered or coated with about 0.3 μm to 1.5 μm of Ag. The silver may be plated, for example, by electroless plating methods. In some example implementations, plating metals other than silver, for example, nickel, gold, or palladium may be used to cover the mechanical locking features to facilitate sintering.

The mechanical locking features will improve the adhesion strength of the sintered joint between the semiconductor device package and the inverter/heat sink when subjected to stress.

FIG. 2A shows an example power electronic substrate 110 in which mechanical interlocking feature 160 is formed by texture features such as indentations in surface S1 of bottom metal layer 110C of power electronic substrate 110. The texture features or indentations may be the V-shaped notches 161 (as shown and discussed above with reference to FIG. 1). FIG. 2B shows an exploded view of a portion A of surface S1 of bottom metal layer 110C (FIG. 2A).

As shown in FIG. 2A, the V-shaped notches 161 may have a depth d and a width w at the textured surface S1 of bottom metal layer 110C. In example implementations, the depth d may be in a range of about 100 μm to 200 μm (e.g., 150 μm) and width w may be a range of about 100 to 400 μm (e.g., 150 μm).

Further, as shown in FIG. 2B, the textured surface S1 of bottom metal layer 110C including the V-shaped notches 161 may be coated with a plated metal layer 263 to facilitate silver sintering. Plated metal layer 263 may be a layer of silver, nickel, gold, or palladium. In example implementations, plated metal layer 263 may have a thickness T across flat portions (portions FP) of the textured surface S1 and a thickness TV inside the V-shaped notches 161 as shown in FIG. 2B. In some example implementations, as shown in FIG. 2B, plated metal layer 263 may have the same thickness on flat portions FP of the textured surface S1 as the thickness inside the V-shaped notches 161 (i.e., T=TV). The plate metal layer thickness may be selected to ensure complete wetting of surface S1 by sinter material layer 150. In example implementations, plated metal layer 263 may have thickness T of about 0.3 μm to 1.5 μm.

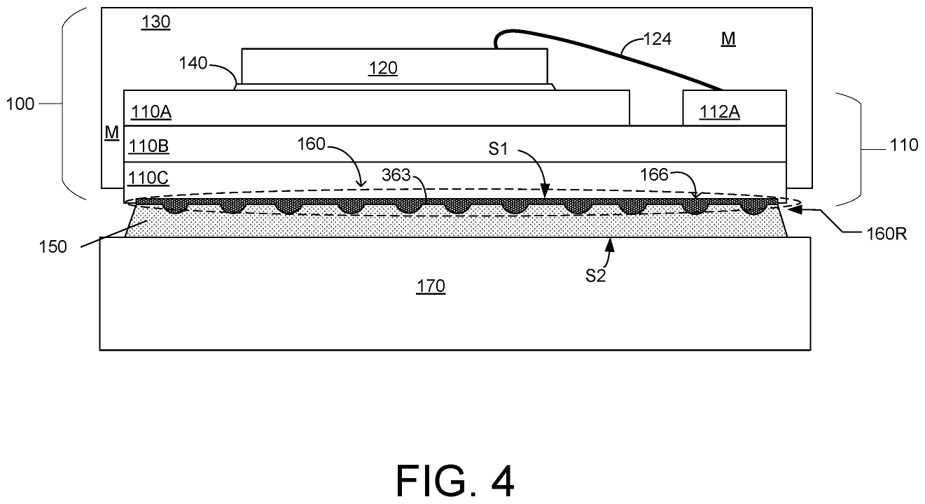

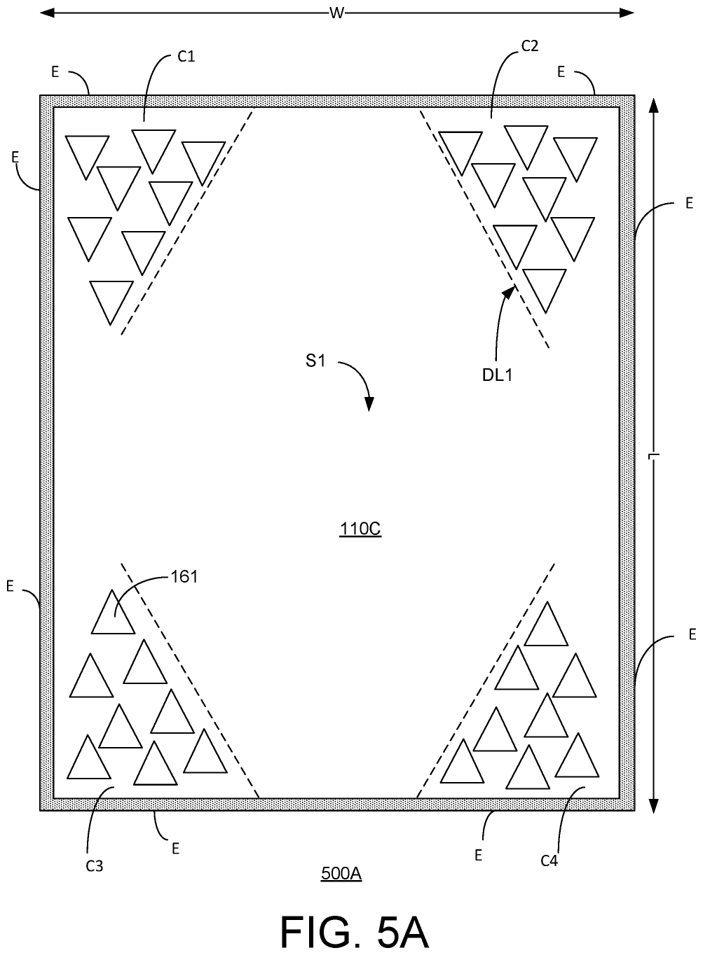

FIG. 3A shows an example power electronic substrate 110 in which mechanical interlocking feature 160 (FIG. 1) includes bumps or protrusions 166 formed in a row 160R on surface S1 of bottom metal layer 110C. The bumps or protrusions 166 may, for example, have a hemispherical or quasi-spherical shape (e.g., partial sphere shapes). FIG. 3B shows an exploded view of a portion B of bottom metal layer 110C (FIG. 3A).

As shown in FIG. 3A, the quasi spherical shape protrusions 166 may have a diameter or width wd (in the x-direction) and a height h (in the y-direction) at the surface S1 of bottom metal layer 110C. In example implementations, the height h may be in a range of about 100 μm to 200 μm (e.g., 150 μm) and the diameter or width wd may be a range of about 100 to 400 μm (e.g., 150 μm).

Further, as shown in FIG. 3B, the textured surface S1 of bottom metal layer 110C including the quasi spherical shape protrusions 166 may be coated with a plated metal layer 363 to facilitate silver sintering. Plated metal layer 363 may, for example, be a layer of silver, nickel, gold, or palladium. In example implementations, plated metal layer 363 may have a thickness T across flat portions (portions FP) of the textured surface S1 and a thickness TC on surfaces of the quasi spherical shape protrusions 166. In some example implementations, as shown in FIG. 3B, plated metal layer 363 may have a thickness TC on the quasi spherical shape protrusions 166 that is less than the thickness T on the flat portions FP of the textured surface S1 (i.e., TC<T). The plate metal layer thicknesses (T, and TC) may be selected to ensure complete wetting of surface S1 by sinter material layer 150. In example implementations, plated metal layer 363 may have thicknesses T and TC, each of about 0.3 μm to 1.5 μm.

The sinter material layer 150 (e.g., silver particle paste) may be disposed between the textured surface S1 of bottom metal layer 110C and top surface S2 of the heat sink block or the metal casing of the application component or module (e.g., heat sink block 170, FIG. 1) that are to be sintered together. Plated metal layer 363 may facilitate the sintering by enhancing wetting of the textured surface S1 of bottom metal layer 110C (including the mechanical interlocking feature 160 (quasi spherical shape protrusions 166)) by sinter material layer 150.

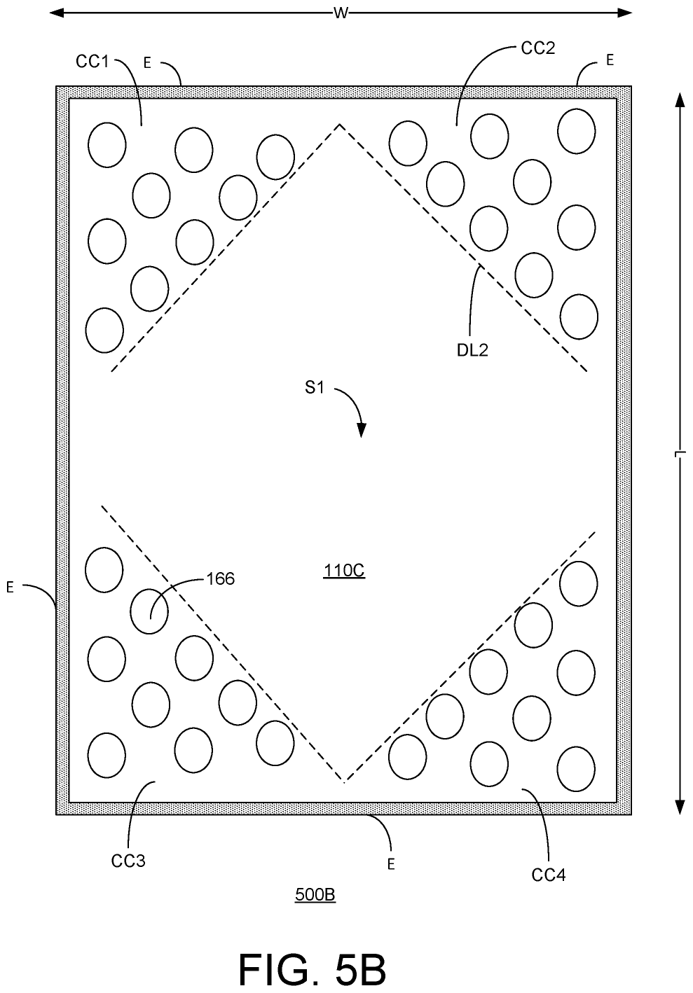

FIG. 4, like FIG. 1, shows a cross sectional view of a semiconductor device package 100 that is surface mounted on heat sink block 170. Semiconductor device package 100 is adhered to heat sink block 170 by a silver sinter material layer 150 and a mechanical interlocking feature 160.

In the example shown in FIG. 4, the mechanical interlocking feature 160 includes a row 160R of quasi spherical shape protrusions 166 disposed on bottom metal layer 110C as shown, for example, in FIG. 3A and FIG. 3B. In FIG. 4, the textured surface S1 of bottom metal layer 110C including the quasi spherical shape protrusions 166 are shown as being coated with a plated metal layer 363 (FIG. 3B) to facilitate sintering.

In the foregoing examples, the mechanical interlocking feature 160 is described and shown as including interlocking features such as V-shaped notches 161 and quasi spherical shape protrusions 166 that are uniformly distributed in rows (e.g., row 160R) on a bottom metal layer of the ceramic substrate (substrate 110) included in the semiconductor device package.

In some example implementations, a number of the interlocking features may be distributed in different areas of the bottom metal layer in proportion to the sintering adhesion strength desired or required in those areas. Areas where the sintering adhesion strength desired or required is greater may have a higher concentration of the interlocking features than areas where the greater sintering adhesion strength is not desired or required. The different areas may have different adhesion strength for support required based, for example, on differences in thermal or mechanical behavior in the different areas.

In example implementations, as noted previously with reference to FIG. 1, the interlocking features (i.e., the texture features—cuts, grooves, notches, protrusions, and/or so forth) may be regularly spaced or may be irregularly spaced across the bottom surface S1 of the metal layer. Further, in some example implementations, the texture features may have a constant or uniform areal density, for example, in the x and y directions, across the bottom surface S1 of metal layer 110C. In some example implementations, the texture features may have a non-constant or varying areal density across the bottom surface S1 of metal layer 110C. For example, some areas (e.g., an edge portion or area) of the bottom surface S1 may have a higher or a lower areal density of texture features than other areas (e.g., a central portion or area) of the bottom surface S1. In some example implementation, the areal density of the texture features may have a gradient across of the bottom surface S1.

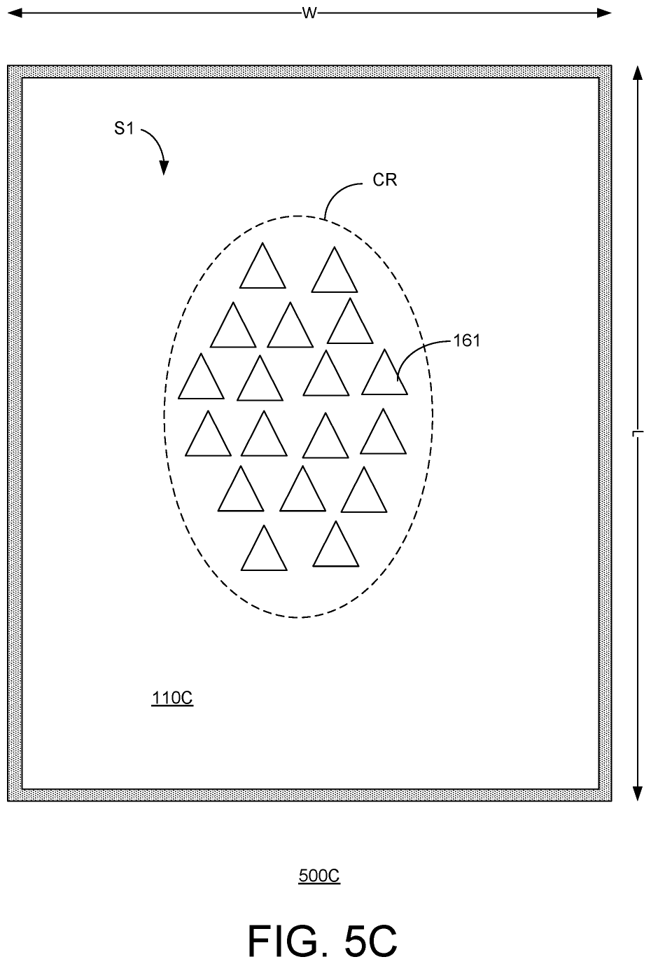

FIGS. 5A through 5C pictorially illustrate examples of different distributions of the interlocking features on the backside of metal layer 110C at the bottom of power electronic substrate 110.

Each of FIGS. 5A through 5C shows bottom textured surface S1 of metal layer 110C that forms an exposed a copper thermal pad at a bottom of the semiconductor device package 100. Metal layer 110C, which may be made of copper, may have for example, a rectangular shape with width W and a length L.

FIG. 5A illustrates an example distribution 500A of the interlocking features on textured surface S1 of metal layer 110C. In distribution 500A, only corner regions (e.g., corner region C1, C2, C3 and C4) of the rectangular shaped metal layer 110C are textured, for example, with V-shaped notches 161. The corner regions C1, C2, C3 and C4 may have a generally a triangular shape bounded by the side edges E of metal layer 110C and, for example, the dashed lines DL1 shown in FIG. 5A. V-shaped notches 161 are present only in these corner regions. V-shaped notches 161 are not present outside the corner regions. This distribution of the V-shaped notches 161 in the corner regions (e.g., corner region C1, C2, C3 and C4) may provide a greater adhesion strength of sinter material to metal layer 110C in the corner regions than in other regions of metal layer 110C.

In some example implementations, the interlocking features (V-shaped notches 161) may be disposed only in some of the corner regions (e.g., corner region C1, or corner regions C1 and C2, or corner regions C1 and C3, etc.). Other corner regions may have a few or none of the interlocking features (e.g., V-shaped notches 161 or protrusions 166).

FIG. 5B illustrates another example distribution 500B of the interlocking features on textured surface S1. In distribution 500B, only corner regions (e.g., corner region CC1, CC2, CC3 and CC4) of the rectangular shaped metal layer 110C are textured, for example, with protrusions 166. The corner regions CC1, CC2, CC3 and CC4 may have a generally a triangular shape bounded by the side edges E of metal layer 110C and, for example, the dashed lines DL2 shown in FIG. 5B. In example implementations, as shown in FIG. 5A and FIG. 5B, the corner regions CC1, CC2, CC3 and CC4 (FIG. 5B) can have larger areas than the corner regions in C1, C2, C3 and C4 (FIG. 5A). Protrusions 166 are present only in the corner regions CC1, CC2, CC3 and CC4. Protrusions 166 are not present outside the corner regions. This distribution of the protrusions 166 in the corner regions (e.g., corner region CC1, CC2, CC3 and CC4) may provide a greater adhesion strength of sinter material to metal layer 110C in the corner regions than in other regions of metal layer 110C.

In some example implementations, the interlocking features (e.g., protrusions 166) may be disposed only in some of the corner regions (e.g., corner region CC1, or corner regions CC1 and CC2, or corner regions CC1 and CC3, etc.). Other corner regions may have a few or none of the interlocking features (e.g., protrusions 166).

In some example implementations, the corner regions may be any shape regions (e.g., circular, or oval regions) that are not necessarily triangular. In some implementations, the corner regions can have an irregular shape that is not triangular. In some implementations, one or more of the corner regions may not have interlocking features. In some example implementations, the texture features may have a constant or uniform areal density, for example, in the x and y directions, across the bottom surface S1 of metal layer 110C. In some other example implementations, the texture features may have a non-constant or varying areal density across the bottom surface S1 of metal layer 110C. For example, some areas (e.g., an edge portion or area) of the bottom surface S1 may have a higher or a lower areal density of texture features than other areas (e.g., a central portion or area) of the bottom surface S1.

In example implementations, the texture features may have gradient in areal density across portions of the bottom surface S1 of metal layer 110C.

FIG. 5C illustrates another example distribution 500C of the interlocking features on textured surface S1. In distribution 500C, only a central region (e.g., central region CR) of the rectangular shaped metal layer 110C is textured, for example, with V-shaped notches 161. In the example distribution 500C there may be no texture features disposed outside the central region CR.

This distribution of V-shaped notches 161 in the central region may provide a greater adhesion strength of sinter material to metal layer 110C in the central region than in other regions of metal layer 110C.

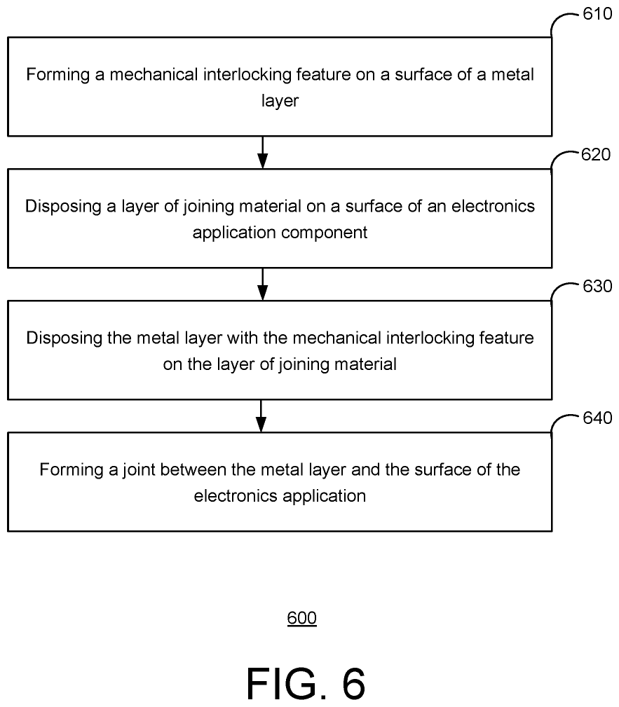

In other example implementations, the interlocking features (V-shaped notches 161 or the protrusions 166) may be disposed both in a corner region or corner regions and a central portion of the rectangular shaped metal layer 110C with an increasing or decreasing density gradient of the interlocking features going from the corner region or corner regions to the central portion. FIG. 6 illustrates an example method 600 for sintering a surface-mounted semiconductor device package to a metal surface of an electronics application component (e.g., an automotive inverter or a heat sink). The semiconductor device package may include a power device disposed on a ceramic substrate and encapsulated in a molding material. The ceramic substrate may be a metalized ceramic substrate (e.g., a direct bonded copper (DBC) substrate, or an advanced metal brazing (AMB) substrate) with metal layers that are plated or bonded on each side of a ceramic substrate in the semiconductor device package. A metal layer bonded to an outer side of the ceramic substrate (on the side opposite to the side on which the semiconductor device is disposed) may be an exposed thermal pad at a bottom of the semiconductor device package.

Method 600 includes forming a mechanical interlocking feature on a surface of a metal layer (610). The surface of the metal layer may be the metal layer surface exposed at the bottom of a semiconductor device package.

Method 600 further includes disposing a layer of joining material on a surface of an electronics application component (620), and disposing the metal layer with the mechanical interlocking feature on the layer of joining material (630). Disposing the metal layer with the mechanical interlocking feature on the layer of sinter material 630 can be such that the mechanical interlocking feature engages the layer of joining material. The mechanical interlocking feature can hold the layer of joining material in place relative to the metal layer surface exposed at the bottom of the semiconductor device package and the surface of the electronics application component.

In some example implementations, the layer of joining material may be a layer of solder material. In some example implementations, the layer of joining material may be a layer of sinter material. The sinter material may be a paste of micron or sub-micron sized particles including, for example, particles of silver, copper, or aluminum, etc. In example implementations, the layer of sinter material may be a silver particle paste.

Method 600 further includes forming a joint between the metal layer and the surface of the electronics application (640). In example implementations, the joint may be a silver sinter joint. Forming the sinter joint may include a low temperature sintering treatment in addition to application of pressure to the components. In example implementations, the low temperature silver sintering may involve sintering temperatures, for example, in a range of about 200° C. to about 400° C. (e.g., 250° C.).

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus, comprising:
a ceramic substrate;
a first metal layer disposed on a first side of the ceramic substrate; and
a second metal layer disposed on a second side of the ceramic substrate,
the second metal layer having an outer surface including a mechanical interlocking feature.

2. The apparatus of claim 1, wherein the mechanical interlocking feature includes at least an indentation formed in the outer surface of the second metal layer.

3. The apparatus of claim 2, wherein the indentation comprises a V-shaped or a U-shaped groove formed in the second metal layer.

4. The apparatus of claim 1, wherein the mechanical interlocking feature includes at least a protrusion formed on the outer surface of the second metal layer.

5. The apparatus of claim 1, wherein the ceramic substrate includes at least one of alumina (Al₂O₃) or aluminum nitride (AlN), and wherein the first metal layer and the second metal layer coupled to opposite sides of the ceramic substrate.

6. The apparatus of claim 1, wherein the ceramic substrate includes silicon nitride (Si₃N₄), and the first metal layer and the second metal layer are copper sheets brazed on to the ceramic substrate.

7. The apparatus of claim 1, wherein the mechanical interlocking feature is configured to hold in position a sinter material layer or a solder material layer disposed between the second metal layer and another metal surface.

8. A substrate comprising:
a ceramic substrate; and
a metal layer disposed on a side of the ceramic substrate,
the metal layer including a plurality of mechanical interlocking features for engaging and holding on to a joining material layer.

9. The substrate of claim 8, wherein the plurality of mechanical interlocking features include at least one of indentations in, or protrusions on, a surface of the metal layer.

10. The substrate of claim 9, wherein the indentations include V-shaped grooves or U-shaped grooves made in the surface of the metal layer.

11. The substrate of claim 9, wherein the protrusions in the surface of the metal layer have a quasi-spherical shape.

12. The substrate of claim 8, wherein the metal layer has a rectangular shape surface and, wherein the plurality of mechanical interlocking features are disposed in a central portion of the rectangular shape surface of the metal layer.

13. The substrate of claim 8, wherein the metal layer has a rectangular shape surface, wherein the plurality of mechanical interlocking features are disposed corner regions of the rectangular shape surface of the metal layer.

14. The substrate of claim 8, wherein the plurality of mechanical interlocking features are evenly spaced across a surface of the metal layer.

15. The substrate of claim 8, wherein the plurality of mechanical interlocking features are unevenly spaced across a surface of the metal layer.

16. A method comprising:
forming a mechanical interlocking feature on a surface of a metal layer;
disposing a layer of joining material on a surface of an electronics application component;
disposing the metal layer with the mechanical interlocking feature on the layer of joining material; and
forming a joint between the metal layer and the surface of the electronics application component.

17. The method of claim 16, wherein the surface of the metal layer is a metal layer surface exposed at a bottom of a semiconductor device package.

18. The method of claim 16, wherein the mechanical interlocking feature comprises texture features of the surface of the metal layer.

19. The method of claim 18, wherein the texture features include at least one of an indentation, a V-shaped groove, a U-shaped groove, or a protrusion.

20. The method of claim 16, wherein disposing the layer of joining material includes disposing a layer of silver particle paste.

21. The method of claim 20, wherein forming the joint includes low temperature silver sintering at temperatures in a range of 200° C. to 400° C.
